(19) United States
(12) Patent Application Publication
(10) Pub. No.: US 2026/0213479 A1
(43) Pub. Date: Jul. 23, 2026

(54) ELECTRICAL CONNECTION UNIT

(71) Applicant: YAZAKI CORPORATION, Tokyo (JP)

(72) Inventors: Thanh Cong Pham, Kakegawa-shi (JP); Ryu Senoo, Kakegawa-shi (JP)

(21) Appl. No.: 19/452,183

(22) Filed: Jan. 16, 2026

(30) Foreign Application Priority Data
Jan. 23, 2025 (JP) 2025-009811

(51) Int. Cl. H01R 25/16; H01R 13/512

(52) U.S. Cl. CPC H01R 25/162; H01R 13/512; H01R 2201/26

(57) ABSTRACT

One embodiment provides an electrical connection unit capable of improving heat radiation performance while realizing high-density mounting. An electrical connection unit of one embodiment is an on-vehicle electrical connection unit including a base portion, a first routing member that has a first extension portion extending in a direction intersecting the base portion and forms an energization path in a first direction intersecting the base portion, and a second routing member that has a thermal load larger than that of the first routing member, has a second extension portion extending in a direction intersecting the base portion, and forms an energization path in the first direction, wherein the first extension portion is inclined at a first angle with respect to the base portion, and wherein the second extension portion is inclined at a second angle smaller than the first angle with respect to the base portion.

### BACKGROUND OF THE INVENTION

### Field of the invention

Embodiments of the present invention relate to an electrical connection unit.

Priority is claimed on Japanese Patent Application No. 2025-009811 filed in Japan on January 23, 2025, the content of which is incorporated herein by reference.

### Description of Related Art

In the electrical connection unit, it is known that electronic components such as relays and resistors are mounted on a mounting surface of a housing. A conductive member (routing member) such as a bus bar is electrically connected to the electronic component.

### Prior art document

### Patent document

Patent Document 1: Japanese Unexamined Patent Application, First Publication No. 2018-113184

### SUMMARY OF THE INVENTION

Incidentally, in the electrical connection unit, it is preferable that electronic components and routing members are mounted at high density. On the other hand, there is a problem that air permeability is deteriorated by high-density mounting and heat radiation performance is deteriorated.

One embodiment provides an electrical connection unit capable of improving heat radiation performance while realizing high-density mounting.

An electrical connection unit of one embodiment is an on-vehicle electrical connection unit including a base portion, a first routing member that has a first extension portion extending in a direction intersecting the base portion and forms an energization path in a first direction intersecting the base portion, and a second routing member that has a thermal load larger than that of the first routing member, has a second extension portion extending in a direction intersecting the base portion, and forms an energization path in the first direction, wherein the first extension portion is inclined at a first angle with respect to the base portion, and wherein the second extension portion is inclined at a second angle smaller than the first angle with respect to the base portion.

According to one embodiment, it is possible to improve heat radiation performance while realizing high-density mounting.

### BRIEF DESCRIPTION OF THE DRAWINGS

FIG. 1 is a perspective view illustrating an electrical connection unit according to an embodiment.

FIG. 2 is an exploded perspective view illustrating a metal cover and a first structure according to the embodiment.

FIG. 3 is an exploded perspective view illustrating the first structure, a relay bus bar, and a part of an external connection bus bar according to the embodiment.

FIG. 4 is an exploded perspective view illustrating the electrical connection unit according to the embodiment.

FIG. 5 is a plan view illustrating the electrical connection unit according to an embodiment.

FIG. 6 is a plan view illustrating the electrical connection unit according to an embodiment as seen through a second cover.

FIG. 7 is a plan view illustrating the inside of an accommodation space of the electrical connection unit of the embodiment.

FIG. 8 is a cross-sectional view taken along line F8-F8 of a structure illustrated in FIG. 7.

FIG. 9 is a cross-sectional view taken along line F9-F9 of the structure illustrated in FIG. 7.

FIG. 10 is a plan view illustrating an electrical connection unit according to a modification example of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. The constitution to be described below does not limit the scope of the embodiment.

In the present disclosure, terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “cover” is not limited to a case where the entire target is covered, and may include a case where only a part of the target is covered. The term “facing” indicates that virtual projection images of two target objects overlap each other when viewed in a specific direction. That is, the term “facing” is not limited to a case where two target objects directly face each other, and may include a case where two target objects face each other in a state in which another member exists between the two target objects. The term “orthogonal”, or “the same” may include “substantially orthogonal”, or “substantially the same”, respectively. The term “sheet-shaped” or “sheet” is not limited to a member having a thickness of 1 mm or more, and may be a member (so-called a film) having a thickness of less than 1 mm.

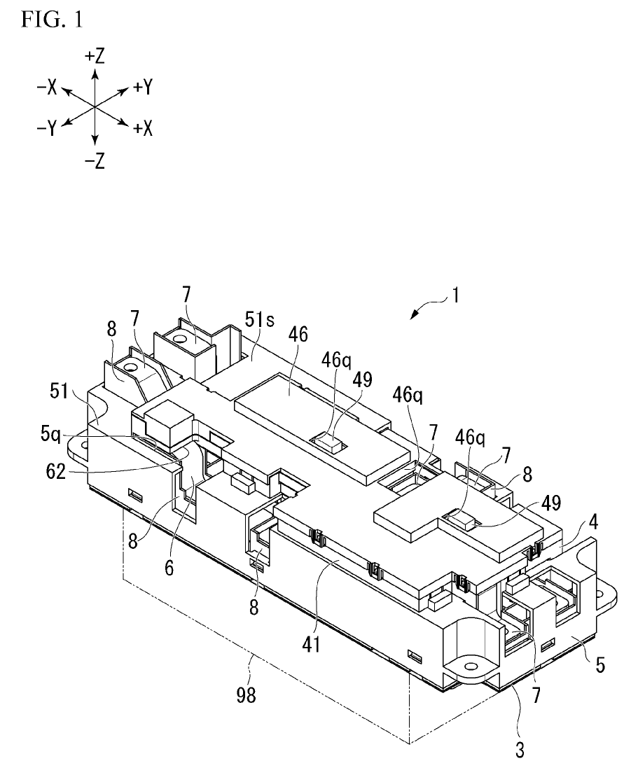

In the present disclosure, a +X direction, a -X direction, a +Y direction, a -Y direction, a +Z direction, and a -Z direction are defined as follows. As illustrated in FIG. 1, an X direction is one direction in a plane along a support surface 51s of a support portion 51 which will be described below. The +X direction is one direction of the X direction. The -X direction is a direction opposite to the +X direction. Hereinafter, the +X direction and the -X direction are simply referred to as the “X direction” in a case where they are not distinguished from each other. A Y direction is a direction intersecting (for example, orthogonal to) the X direction in a plane along the support surface 51s of the support portion 51 which will be described below. The +Y direction is one direction of the Y direction. The -Y direction is a direction opposite to the +Y direction. Hereinafter, the +Y direction and the -Y direction are simply referred to as the “Y direction” in a case where they are not distinguished from each other. The +Z direction and the -Z direction are directions intersecting (for example, orthogonal to) the X direction and the Y direction. The +Z direction is a direction in which the support surface 51s of the support portion 51 which will be described below faces. The -Z direction is a direction opposite to the +Z direction. Hereinafter, in a case where the +Z direction and the -Z direction are not distinguished, the directions will be simply referred to as a “Z direction”. The Z direction is an example of a “first direction”. The Y direction is an example of a “second direction”. Also, the X direction may be referred to as a “third direction”.

Hereinafter, in a case where the X direction and the Y direction are not distinguished, the directions may be referred to as a “horizontal direction”. Hereinafter, the Z direction may be referred to as a “vertical direction”. Hereinafter, the +Z direction side may be referred to as “upper”, and the -Z direction side may be referred to as “lower”. However, these expressions are expressions for convenience of description, and do not limit a gravity direction of an electrical connection unit 1 (an installation posture of the electrical connection unit 1).

### Embodiments

### 1. Constitution of Electrical Connection Unit

The electrical connection unit 1 (The on-vehicle electrical connection unit 1) is provided on the vehicle. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 is connected to a plurality of external devices present outside. The electrical connection unit 1 mediates connection between the plurality of external devices (hereinafter also referred to as a “product”). For example, the external devices may include a battery pack, a load, a charger, and the like. The battery pack is mounted on a vehicle. The load is a device including an inverter or the like for driving a motor of a vehicle driven by using power stored in the battery pack. The charger is a device for supplying power for charging the battery pack. The electrical connection unit 1 may be referred to as an “electrical connection box” or a “junction box”, for example. However, the electrical connection unit 1 is not limited to a box-shaped device.

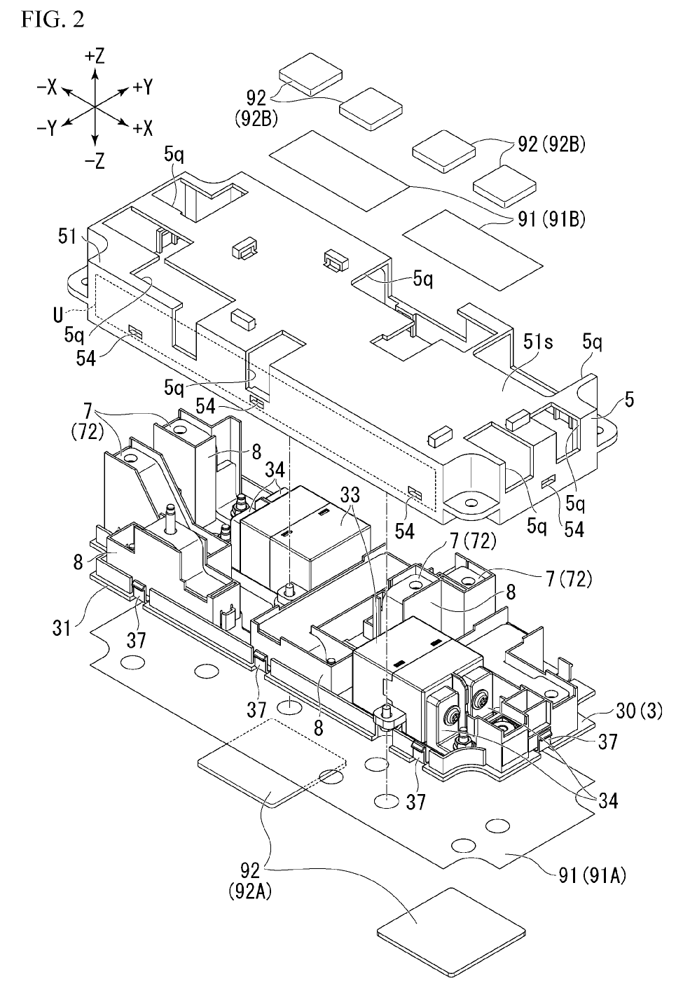

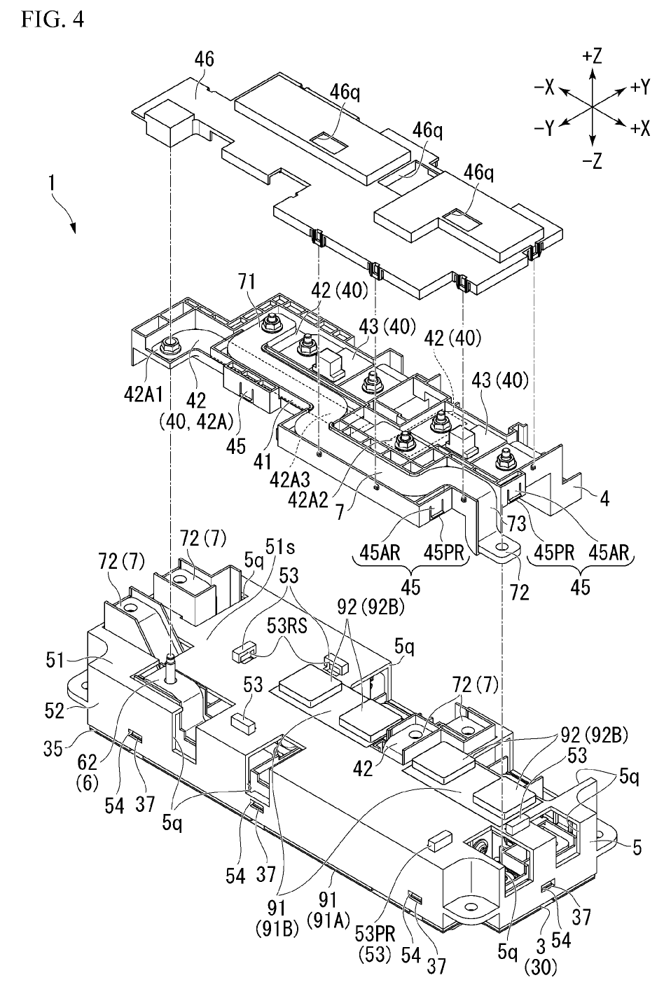

The electrical connection unit 1 includes a first structure 3, a second structure 4, a metal base 5, a relay bus bar 6, a plurality of external connection bus bars 7, and a plurality of auxiliary base members 8. The electrical connection unit 1 further includes an insulating sheet 91 and a heat transfer member 92 (see FIGS. 2 and 4). The second structure 4 is supported by the metal base 5. The second structure 4 is stacked on the first structure 3 with the metal base 5 interposed therebetween in the +Z direction. By this stacking, the electrical connection unit 1 has at least a two-story hierarchical structure. For example, the electrical connection unit 1 may be disposed in contact with a cooling surface of an external cooler 98 from the -Z side. The external cooler 98 may be, for example, a water jacket.

### 2. Constitution of First Structure

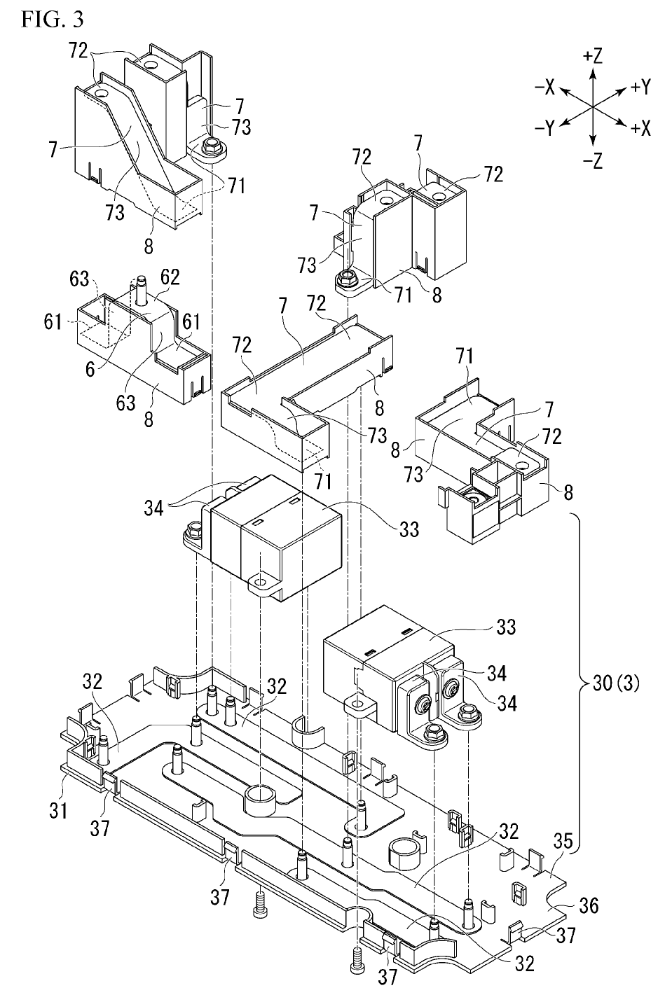

As illustrated in FIG. 2, the first structure 3 includes a first circuit 30. The first circuit 30 includes a routing board 31, a plurality of electronic components 33, and a plurality of connection components 34. As illustrated in FIG. 3, the routing board 31 includes a plurality of bus bars 32 and a base plate 35.

### Electronic Component

Each electronic component 33 is an important component for exerting a function of mediating connection between a plurality of external devices among the electronic components included in the electrical connection unit 1. Each electronic component 33 may be, for example, an electronic component required for the electrical connection unit 1 in common for different products to which the electrical connection unit 1 is applied. The plurality of electronic components 33 may include, for example, a relay (for example, a mechanical relay or a semiconductor relay). The plurality of electronic components 33 may include, for example, a relay capable of switching between conduction and disconnection of the largest current among relays mounted on the electrical connection unit 1. Each electronic component 33 is electrically connected to at least one bus bar 32 among the plurality of bus bars 32. Each electronic component 33 may be electrically connected to the bus bar 32 via a pair of connection components 34, for example.

### Routing Board

The routing board 31 is a substrate for forming at least a part of an energization path connected to the electronic component 33. In the present disclosure, the “routing board” indicates a board-type routing structure. The “board-type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the routing board 31 has a plate shape formed in the X direction and the Y direction. The routing board 31 is an example of a “base portion”. The routing board 31 includes at least one or more routing members (for example, the bus bars 32).

In the routing board 31, the plurality of bus bars 32 and the base plate 35 are integrated through insert molding. The routing board 31 is formed as a single member by insert-molding the bus bar 32 with the base plate 35. That is, the bus bar 32 is integrated with the base plate 35 without using a fastening member such as a screw or a bolt. Note that the routing board 31 may be formed by another structure instead of the insert molding.

### Base Plate

The base plate 35 is a holding member that integrally holds the plurality of bus bars 32 arranged in the horizontal direction at intervals. The base plate 35 is made of, for example, a synthetic resin and has an insulating property. The base plate 35 electrically insulates the plurality of bus bars 32 from each other. The base plate 35 includes a flat surface portion 36 and a plurality of claw portions 37. The base plate 35 may be referred to as an “insulating substrate”.

The flat surface portion 36 is a portion formed in a plate shape in the base plate 35. The flat surface portion 36 has a plate shape formed in the horizontal direction. The flat surface portion 36 forms a main portion of the base plate 35. The flat surface portion 36 forms a base portion (insulating base portion) of the base plate 35. In the present embodiment, the flat surface portion 36 extends over the entire width in the X direction of the base plate 35 and over the entire width in the Y direction of the base plate 35 excluding four corner portions of the base plate 35. The electronic component 33 is placed on the flat surface portion 36 from the +Z direction side of the flat surface portion 36. That is, the electronic component 33 is disposed on the +Z direction side with respect to the flat surface portion 36. The plurality of claw portions 37 are located on the outer periphery of the flat surface portion 36. Each claw portion 37 protrudes from the flat surface portion 36 in the +Z direction.

Each bus bar 32 is a routing member (electrical connection member) included in the routing board 31. Each bus bar 32 is, for example, a routing member for forming at least a part of the energization path electrically connected to the electronic component 33. Each bus bar 32 may be, for example, a routing member for electrically connecting the electronic component 33 to a second circuit 40 or an external device of the electrical connection unit 1. The bus bar 32 is made of a metal (for example, copper or a copper alloy) and has conductivity. At least a part of each bus bar 32 is held by the base plate 35. The plurality of bus bars 32 may include, for example, portions disposed on the same plane.

At least a part of each bus bar 32 has a plate shape formed in the horizontal direction. At least a part of each bus bar 32 extends along the flat surface portion 36. In the present embodiment, each bus bar 32 has a plate shape formed in the horizontal direction over the entire length. The bus bar 32 is a member that forms an energization path in the horizontal direction.

### 3. Constitution of Second Structure

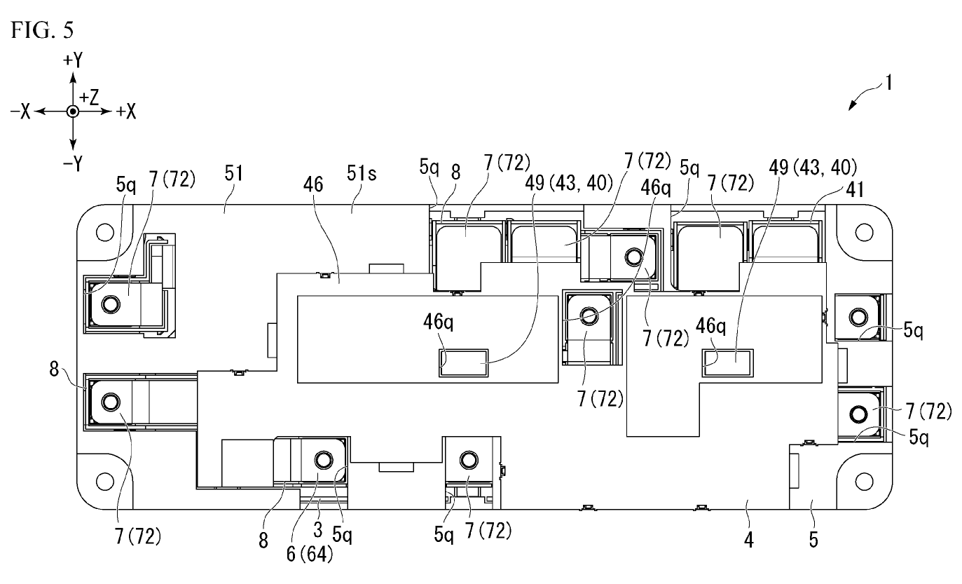

As illustrated in FIGS. 4 to 6, the second structure 4 includes the second circuit 40, a first cover 41, a plurality of lock portions 45, and a second cover 46. The second circuit 40 is supported by the support portion 51. The second circuit 40 includes a plurality of electronic components 43, and a plurality of bus bars 42.

### Electronic Component

Each electronic component 43 is an electronic component for which a degree of freedom in design, component replacement, and the like according to a product to which the electrical connection unit 1 is applied are more likely to be required than the electronic component 33. The electronic component 43 may be, for example, an electronic component in which ease of routing is prioritized for each product to which the electrical connection unit 1 is applied, and may be an electronic component in which a component position in the electrical connection unit 1 is likely to vary. The electronic component 43 may be, for example, an electronic component of which component specification is likely to vary for each product to which the electrical connection unit 1 is applied. The electronic component 43 may be, for example, an electronic component of which the presence or absence of mounting on the electrical connection unit 1 is likely to vary for different products to which the electrical connection unit 1 is applied. The electronic component 43 may be, for example, an electronic component that is likely to be replaced due to component deterioration, periodic maintenance, or the like of the electrical connection unit 1.

The electronic component 43 may be, for example, various sensors (for example, a current sensor or a voltage sensor), a fuse, or a control circuit (for example, a micro controller unit (MCU), a microprocessor unit (MPU), or the like). The electronic component 43 may be, for example, a relay other than a relay that controls conduction and disconnection of the largest current among a plurality of relays mounted on the electrical connection unit 1. Each of the plurality of electronic components 43 is electrically connected to at least one bus bar 42 among the plurality of bus bars 42. The electronic component 43 may include a signal connector 49.

The signal connector 49 is a connector through which a signal related to the electronic component 43 can be input and output. For example, when the electronic component 43 is a current sensor, the signal connector 49 may be able to transmit a detection signal related to the current flowing through the electronic component 43 to the outside of the electrical connection unit 1. For example, when the electronic component 43 is a fuse, the signal connector 49 may be able to transmit an alarm signal for informing the fusing of the electronic component 43 to the outside of the electrical connection unit 1. For example, when the electronic component 43 is a relay, the signal connector 49 may be able to receive a control signal for conduction and disconnection of the electronic component 43 from the outside of the electrical connection unit 1.

Each bus bar 42 is a routing member for forming an energization path in the second circuit 40. Each bus bar 42 may form, for example, an energization path connected to the electronic component 43. At least a part of each bus bar 42 extends in the horizontal direction. The bus bar 42 is made of a metal (for example, copper or a copper alloy) and has conductivity. An end portion of each bus bar 42 may be connected to a terminal of the electronic component 43, the relay bus bar 6, or another bus bar 42 by being fastened with a fastening member such as a screw or a bolt.

### First Cover and Second Cover

Each of the first cover 41 and the second cover 46 has a tray shape in which most (excluding a part) of the outer periphery is erected. The first cover 41 and the second cover 46 are combined such that the directions in which the outer peripheries are erected face each other. The first cover 41 has a plurality of openings 41q. The first cover 41 covers the second circuit 40 from a side in the -Z direction in a portion excluding the plurality of openings 41q. The second cover 46 has a plurality of openings 46q. The second cover 46 covers the second circuit 40 from a side in the +Z direction in a portion excluding the plurality of openings 46q. The first cover 41 and the second cover 46 are combined to accommodate most of the second circuit 40 (for example, a portion of the bus bars 42 excluding a portion to be fastened to the relay bus bar 6 and the signal connector 49). For example, each of the first cover 41 and the second cover 46 may be separated from or in contact with the plurality of bus bars 42 and the plurality of electronic components 43. Each of the first cover 41 and the second cover 46 is made of, for example, a synthetic resin and has an insulating property. The first cover 41 is an example of an “insulating cover”.

### Lock Portion

The plurality of lock portions 45 are located at ends of the second structure 4 on sides in the +X direction, the -X direction, the +Y direction, and the -Y direction. The plurality of lock portions 45 are integrally formed with the second cover 46. The lock portion 45 may be, for example, a snap-fit. The second structure 4 is fixed to the support portion 51 by the plurality of lock portions 45. Each lock portion 45 extends from the outer peripheral upper portion of the first cover 41 toward a first engagement portion 53.

Each lock portion 45 includes an arm portion 45AR and a protrusion 45PR. The arm portion 45AR extends toward the first engagement portion 53 which will be described below. The arm portion 45AR extends from the outer peripheral upper portion of the first cover 41 toward the first engagement portion 53. The arm portion 45AR is deformable so as to warp in the horizontal direction from a posture extending in the Z direction. The arm portion 45AR has a restoring force in a direction opposite to the deformation direction. The protrusion 45PR protrudes from the arm portion 45AR toward the first engagement portion 53 in a direction intersecting the extending direction of the arm portion 45AR.

### 4. Constitution of Metal Base

The metal base 5 includes the support portion 51, a peripheral wall 52, a plurality of the first engagement portions 53, and a plurality of second engagement portions 54. The metal base 5 faces the routing board 31 in the Z direction. The metal base 5 has a plurality of openings 5q. Each opening 5q is open from the outside of the electrical connection unit 1 to an accommodation space U (see FIG. 2) which will be described below. The metal base 5 covers the first structure 3 from a side in the +Z direction excluding the plurality of openings 5q. At least a part of the metal base 5 is made of a metal (for example, made of aluminum or aluminum alloy). The support portion 51, the peripheral wall 52, and the first engagement portion 53 may be integrally formed using, for example, a metal material. The metal base 5 is an example of a “rigid member”, and the support portion 51 is an example of a “first plate portion”. The metal base 5 is also a heat radiation member. Since the metal base 5 is made of a metal, the metal base 5 has a high thermal conductivity, and the metal base 5 easily releases heat inside the metal base 5 to the outside. Also, the opening 5q which will be described below is formed in the metal base 5, and the metal base 5 is designed to have a shape in which internal heat is easily released to the outside through the opening 5q.

### Support Portion

The support portion 51 supports the second structure 4 from a side in the -Z direction. The first circuit 30 is disposed on the -Z direction side with respect to the support portion 51. The second circuit 40 is disposed on the +Z direction side with respect to the support portion 51. The support portion 51 is interposed between the first circuit 30 and the second circuit 40. The support portion 51 has the support surface 51s facing in the +Z direction. The support surface 51s may be, for example, a flat surface.

### Peripheral Wall

The peripheral wall 52 extends in the -Z direction from the outer edge of the support portion 51 to the outer edge of the base plate 35. The peripheral wall 52 closes the outer periphery of a space sandwiched between the support portion 51 and the base plate 35 in a portion excluding the plurality of openings 5q and the plurality of second engagement portions 54. The peripheral wall 52 covers at least the plurality of electronic components 33 from sides in the +X direction, the -X direction, the +Y direction, and the -Y direction. With such a constitution, the plurality of electronic components 33 are accommodated in the accommodation space U (see FIG. 2) defined by the metal base 5 and the routing board 31.

### Engagement Portion

Each first engagement portion 53 protrudes from the support portion 51 in the +Z direction. The first engagement portion 53 has a recess 53RS. The recess 53RS is defined by being surrounded by an edge of the first engagement portion 53 protruding in the horizontal direction. The recess 53RS is recessed in a direction in which the protrusion 45PR extends from the arm portion 45AR. When the first cover 41 is brought closer to the support portion 51 in the -Z direction, the protrusion 45PR climbs over the edge of the first engagement portion 53 around the recess 53RS and is fitted into the recess 53RS. Due to such engagement between the first engagement portion 53 and the lock portion 45, the second structure 4 is maintained in a state of being attached to the metal base 5.

Each second engagement portion 54 is located closer to the -Z direction side of the peripheral wall 52. Each second engagement portion 54 is caught by the tip end of the related claw portion 37. By this catch, the metal base 5 holds the base plate 35. The second engagement portion 54 may be, for example, an opening that opens the peripheral wall 52 in the horizontal direction. Each second engagement portion 54 is not limited to the opening, and may be a recess recessed from the inner peripheral surface of the peripheral wall 52. On the other hand, each claw portion 37 may have any lock structure as long as it can be hooked onto the related second engagement portion 54.

### Opening

Among the plurality of openings 5q, the opening 5q related to the relay bus bar 6 is disposed at a position where the first circuit 30 and the second circuit 40 can be electrically connected. The opening 5q related to the relay bus bar 6 may be disposed, for example, at a position where the relay bus bar 6 is exposed from the metal base 5 in the +Z direction. Among the plurality of openings 5q, the opening 5q related to the external connection bus bar 7 is disposed at a position where the external connection bus bar 7 can pass between the -Z direction side of the support portion 51 and the +Z direction side of the support portion 51.

### 5. Constitution of Relay Bus Bar

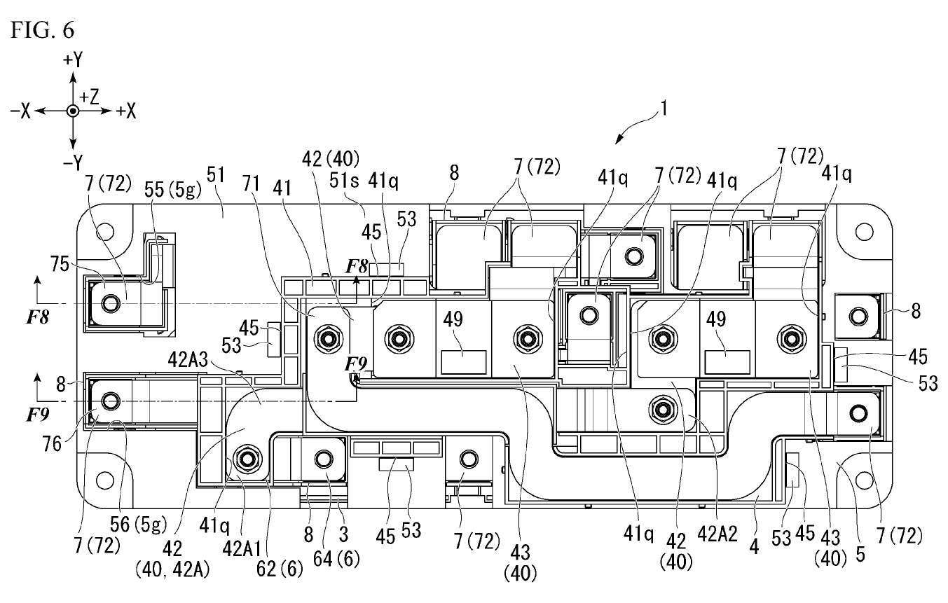

The relay bus bar 6 is electrically connected to the bus bar 32 and the bus bar 42 so as to relay the bus bar 32 and the bus bar 42. The relay bus bar 6 is a member that forms an energization path in the vertical direction. The relay bus bar 6 includes connection portions 61 and 62 and an extension portion 63. The connection portion 61 is electrically connected to the bus bar 32, for example. Two connection portions 61 are provided. For example, one of the two connection portions 61 may be fastened to one end of the bus bar 32 with a fastening member such as a screw or a bolt in an energizable manner. For example, the other of the two connection portions 61 may be fastened to one end of a routing member (for example, a bus bar) extending from a device outside the electrical connection unit 1 with a fastening member such as a screw or a bolt in an energizable manner to each other. The connection portion 62 is disposed on the +Z direction side with respect to the connection portion 61. The connection portion 62 is electrically connected to the bus bar 42, for example (see FIG. 6). For example, the connection portion 62 may be fastened to one end of the bus bar 42 with a fastening member such as a screw or a bolt in an energizable manner. The extension portion 63 extends over the connection portion 61 and the connection portion 62. The extension portion 63 is provided between the connection portion 61 and the connection portion 62. The extension portion 63 connects the connection portion 61 to the connection portion 62.

### 6. Constitution of External Connection Bus Bar

The plurality of external connection bus bars 7 are bus bars for electrically connecting an external device to the first circuit 30 or the second circuit 40. Each external connection bus bar 7 includes connection portions 71 and 72 and an extension portion 73. The connection portion 71 is electrically connected to the bus bar 32 or the bus bar 42. For example, the connection portion 71 may be fastened to one end of the bus bar 32 or the bus bar 42 with a fastening member such as a screw or a bolt in an energizable manner. In at least one external connection bus bar 7 of the external connection bus bars 7, the connection portion 71 may be disposed, for example, on the +Z direction side with respect to the support surface 51s (see FIG. 4). The connection portion 72 can be electrically connected to a routing member (for example, a bus bar) extending from an external device. The connection portion 72 is disposed on the +Z direction side or the -Z direction side with respect to the connection portion 71. In at least some external connection bus bars 7 of the external connection bus bars 7, the connection portion 72 may be disposed, for example, on the +Z direction side with respect to the support surface 51s (see FIG. 4). Some of the connection portions 72 may be fastened to a routing member (for example, a bus bar) extending from an external device with a fastening member such as a screw or a bolt, for example. Some of the connection portions 72 may be connected to a routing member (for example, a bus bar) extending from an external device by welding, for example. The extension portion 73 extends over the connection portion 71 and the connection portion 72. The extension portion 73 is provided between the connection portion 71 and the connection portion 72. The extension portion 73 connects the connection portion 71 to the connection portion 72.

The plurality of external connection bus bars 7 include two external connection bus bars 7 disposed at an end portion of the electrical connection unit 1 on the -X direction side. One of the two external connection bus bars 7 is referred to as a first bus bar 75, and the other thereof is referred to as a second bus bar 76. Structures of the first bus bar 75 and the second bus bar 76 and peripheral structures of the first bus bar 75 and the second bus bar 76 will be described in detail below.

### 7. Constitution of Auxiliary Base Member

The plurality of auxiliary base members 8 are support members that assist three-dimensional routing of various bus bars. Each of the plurality of auxiliary base members 8 supports the relay bus bar 6 or the external connection bus bar 7 from the -Z direction side. The auxiliary base member 8 may support, for example, two external connection bus bars 7. The auxiliary base member 8 is disposed between the routing board 31 and the related bus bar among the relay bus bar 6 and the external connection bus bar 7 in the Z direction. The auxiliary base member 8 is made of, for example, a synthetic resin and has an insulating property.

### 8. Constitution of Insulating Sheet

A plurality of insulating sheets 91 are insulating members for insulating the first circuit 30 and the second circuit 40. As illustrated in FIG. 2, each insulating sheet 91 has a sheet shape formed in the horizontal direction. Each insulating sheet 91 has an insulating property. Each insulating sheet 91 is made of, for example, a synthetic resin such as polyester or polyimide. The plurality of insulating sheets 91 include a first insulating sheet 91A and a pair of second insulating sheets 91B.

The first insulating sheet 91A is disposed on the -Z direction side of the first circuit 30. For example, the first insulating sheet 91A is disposed so as to be in contact with a surface on the -Z direction side of the routing board 31. The first insulating sheet 91A may be disposed, for example, between the routing board 31 and a pair of first heat transfer members 92A which will be described below.

As illustrated in FIG. 4, the pair of second insulating sheets 91B are disposed on the -Z direction side of the second circuit 40. The pair of second insulating sheets 91B faces the support surface 51s, for example. The pair of second insulating sheets 91B are disposed so as to be in contact with the support surface 51s, for example. Each second insulating sheet 91B may be disposed, for example, between the support surface 51s and a pair of related second heat transfer members 92B among two pairs of second heat transfer members 92B which will be described below.

### 9. Constitution of Heat Transfer Member

A plurality of heat transfer members 92 are members for transferring heat (Joule heat) generated by the first circuit 30 and the second circuit 40 at the time of energization to the outside of the first circuit 30 and the second circuit 40. Each heat transfer member 92 is, for example, a heat transfer sheet (for example, a thermally conductive silicone sheet) having elasticity. Each heat transfer member 92 may be made of, for example, a material having higher thermal conductivity than the base plate 35. However, each heat transfer member 92 is not limited to the above example, and may be a heat transfer member made of a thermally conductive gel or another material. As illustrated in FIG. 2, the plurality of heat transfer members 92 include the pair of first heat transfer members 92A and the two pairs of second heat transfer members 92B.

The pair of first heat transfer members 92A is disposed between the cooling surface (see FIG. 1) of the external cooler 98 and the first insulating sheet 91A. For example, each first heat transfer member 92A may be disposed at a position overlapping the related electronic component 33 when viewed in the Z direction.

As illustrated in FIG. 4, the two pairs of second heat transfer members 92B are disposed between the pair of second insulating sheets 91B and the second circuit 40. Each pair of the two pairs of second heat transfer members 92B faces a surface of the related second insulating sheet 91B which faces in the +Z direction. Each pair of the two pairs of second heat transfer members 92B faces a surface of the related electronic component 43 which faces in the -Z direction. Each pair of second heat transfer members 92B may be disposed at a position overlapping the related electronic component 43 when viewed in the Z direction. For example, each electronic component 43 may be placed on the support portion 51 via the bus bar 42 or the external connection bus bar 7, the second heat transfer members 92B, and the second insulating sheet 91B.

### 10. Constitution of First Bus Bar and Second Bus Bar

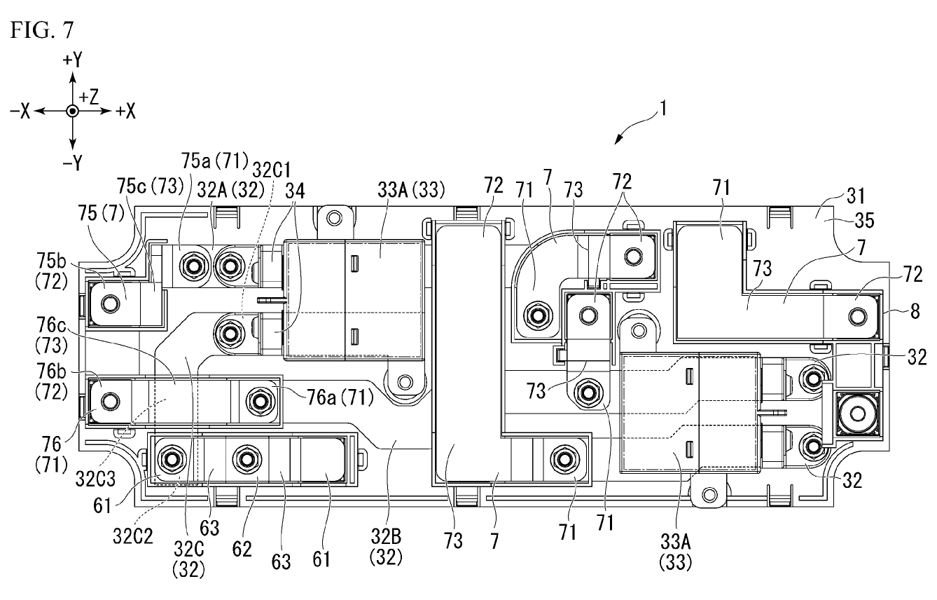

As illustrated in FIGS. 7 to 9, the first bus bar 75 and the second bus bar 76 are disposed at the end portion of the electrical connection unit 1 on the -X direction side. In the illustrated example, the first bus bar 75 and the second bus bar 76 are disposed at positions adjacent to each other in the Y direction. Also, the first bus bar 75 and the second bus bar 76 are disposed on a surface of the routing board 31 on the +Z direction side (upper side). The first bus bar 75 and the second bus bar 76 extend upward. Also, the first bus bar 75 and the second bus bar 76 are disposed on a side opposite to the cooler 98 (for example, a water jacket) in the Z direction with the routing board 31 interposed therebetween. The first bus bar 75 is an example of a “first routing member”, and the second bus bar 76 is an example of a “second routing member”.

### First Bus Bar

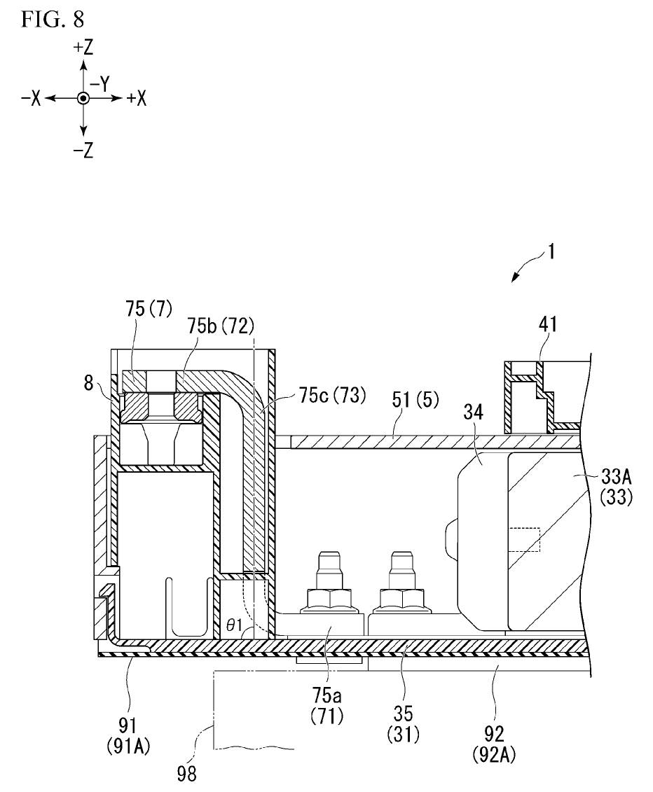

As illustrated in FIGS. 7 and 8, the first bus bar 75 includes a first end portion 75a, a second end portion 75b, and a first extension portion 75c. In the present embodiment, the first end portion 75a is the connection portion 71 of the external connection bus bar 7 described above. The first end portion 75a is connected to one end of the bus bar 32 of the routing board 31 (base portion). In the present embodiment, the second end portion 75b is the connection portion 72 of the external connection bus bar 7 described above. The second end portion 75b is located on a side opposite to the first end portion 75a in the Z direction, and is disposed away from the routing board 31 in the Z direction.

The first extension portion 75c is an extension portion that connects the first end portion 75a and the second end portion 75b. In the present embodiment, the first extension portion 75c is the extension portion 73 of the external connection bus bar 7 described above. The first extension portion 75c extends in a direction intersecting the routing board 31. The first extension portion 75c forms a passage in a direction (Z direction) intersecting the routing board 31. The first extension portion 75c is inclined at a first angle θ1 with respect to the routing board 31. In the present embodiment, it is designed that the first angle θ1 is 90 degrees, and the first extension portion 75c extends perpendicularly to the routing board 31.

At least a part of the first bus bar 75 overlaps one opening 5q of the plurality of openings 5q formed in the support portion 51 (first plate portion) of the metal base 5 (rigid member) in the Z direction when viewed in the Z direction (first direction). Hereinafter, among the openings 5q of the support portion 51, the opening 5q overlapping at least a part of the first bus bar 75 is referred to as a first opening 55. The first extension portion extends to a side (+Z direction side) opposite to the base portion with respect to the support portion 51 through the first opening 55. The second end portion 75b is disposed on the +Z direction side with respect to the support portion 51 while overlapping the first opening 55 in the Z direction.

Also, the first end portion 75a of the first bus bar 75 is connected to one end of one bus bar 32 included in the routing board 31. Hereinafter, the bus bar 32 connected to the first end portion 75a of the first bus bar 75 is referred to as a third bus bar 32A. The third bus bar 32A connects the first bus bar 75 and one electronic component 33. Hereinafter, the electronic component 33 connected to the first bus bar 75 via the third bus bar 32A is referred to as a “first electronic component 33A”.

### Second Bus Bar

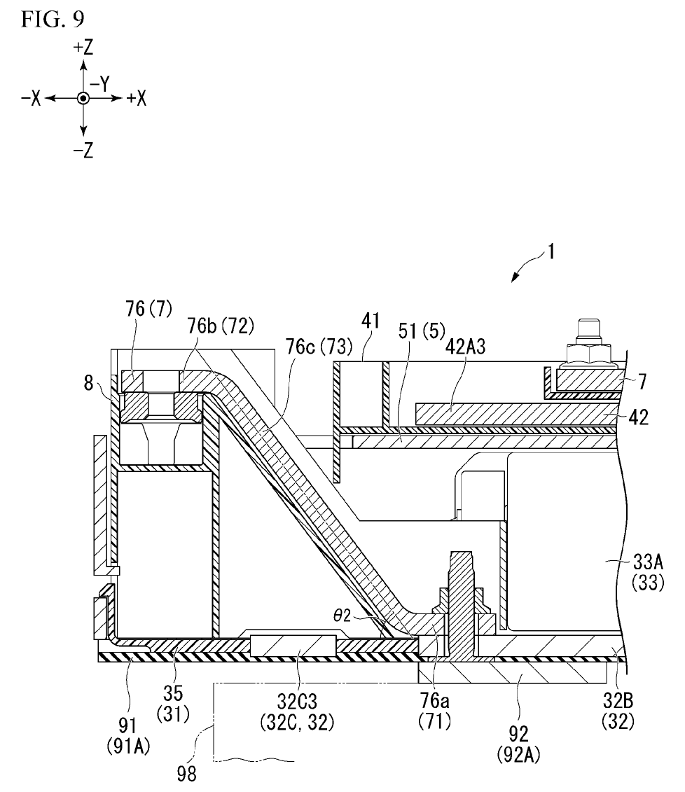

As illustrated in FIG. 7, the second bus bar 76 is disposed at a position closer to the first electronic component 33A than the first bus bar 75. With such an arrangement relationship, the second bus bar 76 is likely to have a higher temperature than the first bus bar 75. That is, the thermal load of the second bus bar 76 is larger than the thermal load of the first bus bar 75. As illustrated in FIGS. 7 and 9, the second bus bar 76 includes a third end portion 76a, a fourth end portion 76b, and a second extension portion 76c. In the present embodiment, the third end portion 76a is the connection portion 71 of the external connection bus bar 7 described above. The third end portion 76a is connected to one end of the bus bar 32 of the routing board 31. In the present embodiment, the third end portion 76a is the connection portion 72 of the external connection bus bar 7 described above. The fourth end portion 76b is located on a side opposite to the third end portion 76a in the Z direction, and is disposed away from the routing board 31 in the Z direction. The fourth end portion 76b is disposed away from the routing board 31 in the Z direction by the same distance as that in the second end portion 75b. Also, the fourth end portion 76b is provided to be adjacent to the third end portion 76a in the X direction.

The second extension portion 76c is an extension portion that connects the third end portion 76a and the fourth end portion 76b. In the present embodiment, the second extension portion 76c is the extension portion 73 of the external connection bus bar 7 described above. The second extension portion 76c extends in a direction intersecting the routing board 31. The second extension portion 76c forms a passage in a direction (Z direction) intersecting the routing board 31. The second extension portion 76c is inclined at a second angle θ2 smaller than the first angle θ1 with respect to the routing board 31. In the present embodiment, the second extension portion 76c extends obliquely with respect to the routing board 31. The second extension portion 76c extends in the -X direction from the third end portion 76a toward the fourth end portion 76b. The second extension portion 76c is located on the +Z direction side as it is located on a side in the -X direction.

At least a part of the second bus bar 76 overlaps one opening 5q of the plurality of openings 5q formed in the support portion 51 of the metal base 5 in the Z direction when viewed in the Z direction. Hereinafter, among the openings 5q of the support portion 51, the opening 5q overlapping at least a part of the second bus bar 76 is referred to as a second opening 56. The second opening 56 is formed such that the opening area of the second opening 56 is greater than the opening area of the first opening 55. The second extension portion extends to a side (+Z direction side) opposite to the base portion with respect to the support portion 51 through the second opening 56. The fourth end portion 76b is disposed on the +Z direction side with respect to the support portion 51 while overlapping the second opening 56 in the Z direction.

Also, the third end portion 76a of the second bus bar 76 is connected to one end of one bus bar 32 included in the routing board 31. Hereinafter, the bus bar 32 connected to the third end portion 76a of the second bus bar 76 is referred to as a fourth bus bar 32B. The fourth bus bar 32B connects the second bus bar 76 and the electronic component 33. The fourth bus bar 32B is connected to the electronic component 33 different from the electronic component 33 to which the third bus bar 32A is connected. Hereinafter, the electronic component 33 connected to the second bus bar 76 via the fourth bus bar 32B is referred to as a “second electronic component 33B”.

Also, at least a part of one bus bar 32 included in the routing board 31 is disposed below a part of the second bus bar 76. The bus bar 32 disposed below the second bus bar 76 is referred to as a “fifth bus bar 32C”. The fifth bus bar 32C is an example of a “fifth routing member”. For example, the fifth bus bar 32C connects the connection portion 61 of the relay bus bar 6 and the connection component 34 connected to the electronic component 33. The fifth bus bar 32C has a fifth end portion 32C1, a sixth end portion 32C2, and a third extension portion 32C3. The fifth end portion 32C1 is connected to the connection portion 61 of the relay bus bar 6. The sixth end portion 32C2 is connected to the electronic component 33 via the connection component 34. The third extension portion 32C3 is an extension portion that connects the fifth end portion 32C1 and the sixth end portion 32C2. The third extension portion 32C3 is disposed below the second extension portion 76c of the second bus bar 76. The third extension portion 32C3 extends in the Y direction below the second extension portion 76c.

Also, at least a part of the first cover 41 (insulating cover) and at least a part of one bus bar 42 accommodated in the first cover 41 are disposed above a part of the second bus bar 76. The bus bar 42 disposed above the second bus bar 76 is referred to as a “sixth bus bar 42A”. The sixth bus bar 42A is an example of a “sixth routing member”. The sixth bus bar 42A includes a seventh end portion 42A1, an eighth end portion 42A2, and a fourth extension portion 42A3 (see FIG. 6). The seventh end portion 42A1 is fastened to the connection portion 61 of the relay bus bar 6 with a fastening member such as a screw or a bolt in an energizable manner. The eighth end portion 42A2 is electrically connected to the electronic component 43 via the other bus bar 42. The eighth end portion 42A2 is fastened to a connection end of the other bus bar 42 with a fastening member such as a screw or a bolt. The fourth extension portion 42A3 is an extension portion that extends in the horizontal direction and connects the seventh end portion 42A1 and the eighth end portion 42A2. The fourth extension portion 42A3 is disposed above the third end portion 76a of the second bus bar 76 with the support portion 51 interposed therebetween. Also, at least an end portion of the sixth bus bar 42A on the -X direction side of the fourth extension portion 42A3 is located at a position lower than that of the fourth end portion 76b of the second bus bar 76.

Also, at least a part of the second bus bar 76 (in the illustrated example, the third end portion 76a) is located closer to the central portion of the metal base 5 (heat radiation member) than the first bus bar 75 when viewed in the Z direction.

### 11. Advantages

In the present embodiment, the electrical connection unit 1 includes the routing board 31 (base portion), the first bus bar 75 (first routing member), and the second bus bar 76 (second routing member). The first bus bar 75 has the first extension portion 75c that extends in a direction intersecting the routing board 31. The first bus bar 75 forms the energization path in the Z direction (first direction) intersecting the routing board 31. The second routing member has a larger thermal load than the first bus bar 75. The second bus bar 76 has the second extension portion 76c that extends in a direction intersecting the routing board 31. The second bus bar 76 forms the energization path in the Z direction. The first extension portion 75c is inclined at the first angle θ1 with respect to the routing board 31, and the second extension portion 76c is inclined at the second angle θ2 smaller than the first angle θ1 with respect to the routing board 31. According to this constitution, the second extension portion 76c of the second bus bar 76 is provided to be inclined more than the first extension portion 75c of the first bus bar 75. Due to this shape difference, the length of the first bus bar 75 having a small thermal load in a direction (horizontal direction, for example, Y direction) intersecting the Z direction can be shortened. Therefore, the constituent components of the electrical connection unit 1 can be disposed densely in the horizontal direction, and thus high-density mounting can be realized. On the other hand, with respect to the second bus bar 76 having a large thermal load, the air around the second bus bar 76 is easily discharged to the +Z direction side along the second extension portion 76c. The flow of air in the second bus bar 76 promotes heat radiation from the second extension portion 76c (chimney effect), thereby improving heat radiation performance.

In the present embodiment, the routing board 31 includes one or more bus bars 32 (routing members). The first bus bar 75 has the first end portion 75a and the second end portion 75b. The first end portion 75a is connected to the routing board 31. The second end portion 75b is located on a side opposite to the first end portion 75a, and is disposed away from the routing board 31 in the Z direction. The second routing member has the third end portion 76a and the fourth end portion 76b. The third end portion 76a is connected to the routing board 31. The fourth end portion 76b is located on a side opposite to the third end portion 76a, and is disposed away from the base portion in the Z direction. The second end portion 75b and the fourth end portion 76b are disposed away from the routing board 31 in the Z direction by the same distance. The first extension portion 75c is the extension portion 73 that connects the first end portion 75a and the second end portion 75b, and the second extension portion 76c is the extension portion that connects the third end portion 76a and the fourth end portion 76b. According to this constitution, while the heat radiation performance is improved by the inclination of the second extension portion 76c, the heights of the second end portion 75b and the first end portion 75a in the Z direction can be aligned.

In the present embodiment, the first extension portion 75c extends perpendicularly to the routing board 31. The second extension portion 76c extends obliquely with respect to the routing board 31. According to this constitution, the length of the first bus bar 75 in a direction intersecting the Z direction can be shortened as much as possible. Therefore, the constituent components of the electrical connection unit 1 can be mounted with higher density.

In the present embodiment, the electrical connection unit 1 includes the metal base 5 (rigid member). The metal base 5 includes the support portion 51 (first plate portion) that faces the routing board 31 in the Z direction. The support portion 51 has the first opening 55 and the second opening 56. The first opening 55 overlaps at least a part of the first bus bar 75 when viewed in the Z direction. The second opening 56 overlaps at least a part of the second bus bar 76 when viewed in the Z direction. The opening area of the second opening 56 is larger than the opening area of the first opening 55. According to this constitution, the air around the second bus bar 76 is easily discharged to the outside through the second opening 56. With such an action, the heat of the second bus bar 76 is easily discharged to the outside, and the heat radiation performance is further improved.

In the present embodiment, the first extension portion 75c extends to a side opposite to the routing board 31 with respect to the support portion 51 through the first opening 55. The second extension portion 76c extends to a side opposite to the routing board 31 with respect to the support portion 51 through the second opening 56. According to this constitution, while the heat radiation performance is improved by the inclination of the second extension portion 76c, the directions of the first extension portion 75c and the second extension portion 76c can be aligned.

In the present embodiment, the first bus bar 75 and the second bus bar 76 are disposed on the surface of the routing board 31 on the +Z direction side (upper side). The first bus bar 75 and the second bus bar 76 extend upward. According to this constitution, the air around the first bus bar 75 and the second bus bar 76 is easily discharged upward by the convection action. That is, the chimney effect is promoted. Therefore, the heat of the first bus bar 75 and the second bus bar 76 is easily radiated, and the heat radiation performance is further improved. Also, in the present embodiment, the first bus bar 75 and the second bus bar 76 are disposed on a side opposite to the cooler 98 in the Z direction with the routing board 31 interposed therebetween. Therefore, the temperature difference between the upper side and the lower side of the first bus bar 75 and the second bus bar 76 becomes large, and the air around the first bus bar 75 and the second bus bar 76 is more easily discharged by the convection action.

In the present embodiment, the routing board 31 includes the fifth bus bar 32C (fifth routing member) disposed below a part of the second bus bar 76. According to this constitution, the fifth bus bar 32C can be disposed in the space formed below the second bus bar 76. Therefore, the space in the electrical connection unit 1 can be used without waste, and thus the constituent components of the electrical connection unit 1 can be mounted with higher density.

In the present embodiment, the electrical connection unit 1 further includes the sixth bus bar 42A (sixth routing member) and the first cover 41 (insulating cover). The first cover 41 accommodates the sixth bus bar 42A. At least a part of the sixth bus bar 42A and at least a part of first cover 41 are disposed above a part of the second bus bar 76. According to this constitution, the sixth bus bar 42A can be disposed in the space formed above the second bus bar 76. Therefore, the space in the electrical connection unit 1 can be used without waste, and thus the constituent components of the electrical connection unit 1 can be mounted with higher density.

In the present embodiment, at least a part of the second bus bar 76 is located closer to the central portion of the metal base 5 (heat radiation member) than the first bus bar 75 when viewed in the Z direction. According to this constitution, at least a part of the second bus bar 76 has a larger gap from the peripheral wall 52 of the metal base 5 than the first bus bar 75. Therefore, air flows more easily around the second bus bar 76 than around the first bus bar 75. Therefore, the heat of the second bus bar 76 is easily discharged. Therefore, the heat radiation effect is further promoted.

### Modification Example

Next, several modification examples will be described. Note that a constitution other than that described below in each modification example is the same as the constitution of the above-described embodiment.

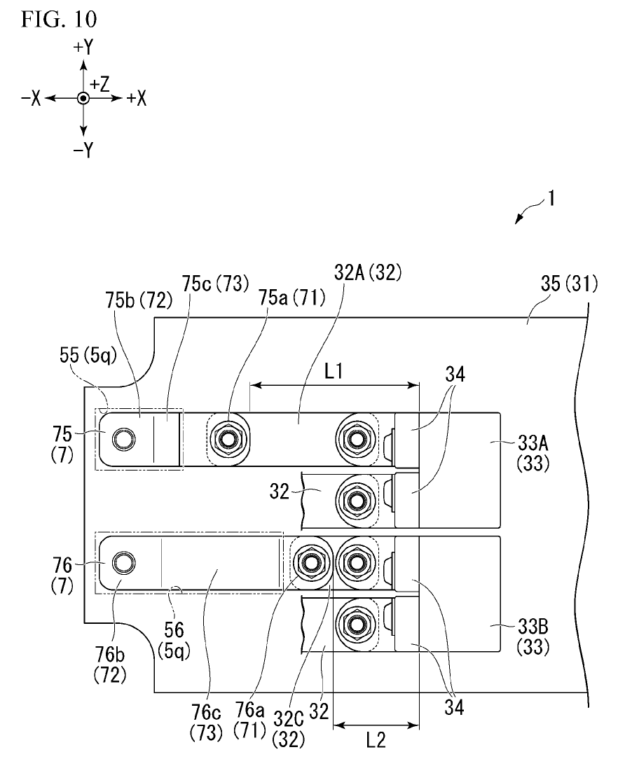

For example, as shown in FIG. 10, the third bus bar 32A that connects the second bus bar 76 and the second electronic component 33B may be shorter than the fourth bus bar 32B that connects the first bus bar 75 and the first electronic component 33A. The third bus bar 32A is an example of a “third routing member”, and the fourth bus bar 32B is an example of a “fourth routing member”. The distance (in the illustrated example, a distance L2 in the X direction) between the second bus bar 76 and the second electronic component 33B is shorter than the distance (in the illustrated example, a distance L1 in the X direction) between the first bus bar 75 and the first electronic component 33A. In this case, the heat received by the second bus bar 76 from the second electronic component 33B to be connected becomes larger than the heat received by the first bus bar 75 from the first electronic component 33A to be connected, and there is a concern that the thermal load of the second bus bar 76 increases. However, as described above, since the second extension portion 76c of the second bus bar 76 is inclined more than the first extension portion 75c of the first bus bar 75, the air around the second bus bar 76 is easily discharged to the outside along the second extension portion 76c, and thus the heat is easily radiated from the second bus bar 76 and the thermal load on the second bus bar 76 can be reduced. Further, similarly to the above-described embodiment, the opening area of the second opening 56 is larger than the opening area of the first opening 55, and thus the air around the second bus bar 76 is easily discharged to the outside.

In the above-described embodiment, the case where some of the plurality of external connection bus bars 7 are the first bus bar 75 (first routing member) or the second bus bar 76 (second routing member) has been described, but the present invention is not limited thereto. For example, the constitution of the first bus bar 75 (first routing member) or the second bus bar 76 (second routing member) described above may be applied to the relay bus bar 6.

In the above-described embodiment, the case where the first bus bar 75 (first routing member) or the second bus bar 76 (second routing member) extends in the X direction has been described, but the present invention is not limited thereto. The first bus bar 75 (first routing member) or the second bus bar 76 (second routing member) may extend, for example, in the Y direction.

In the above-described embodiment, the case where all the first to sixth routing members are bus bars has been described, but the present invention is not limited thereto. The first to sixth routing members may be any members capable of forming the energization path. For example, the first to sixth routing members may be electric wires.

In the above-described embodiment, the routing board 31 in the plate shape has been described as an example of the base portion, but the present invention is not limited thereto. The shape of the base portion is not limited to the plate shape. The base portion may be formed in, for example, a block shape.

Several embodiments and modification examples have been described above. However, the embodiments and the modification examples are not limited to the examples described above. For example, a plurality of embodiments may be realized in combination with each other.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 Electrical connection unit

3 First structure

4 Second structure

5 Metal base (rigid member)

5q Opening

6 Relay bus bar

7 External connection bus bar

8 Auxiliary base member

30 First circuit

31 Routing board (base portion)

32 Bus bar (routing member)

32A Third bus bar (third routing member)

32B Fourth bus bar (fourth routing member)

32C Fifth bus bar (fifth routing member)

32C1 Fifth end portion

32C2 Sixth end portion

32C3 Third extension portion

33 Electronic component

33A First electronic component

33B Second electronic component

34 Connection component

35 Base plate

36 Flat surface portion

37 Claw portion

40 Second circuit

41 First cover (insulating cover)

41q Opening

42 Bus bar

42A Sixth bus bar (sixth routing member)

42A1 Seventh end portion

42A2 Eighth end portion

42A3 Fourth extension portion

43 Electronic component

45 Lock portion

45AR Arm portion

45PR Protrusion

46 Second cover

46q Opening

49 Signal connector

51 Support portion (first plate portion)

51s Support surface

52 Peripheral wall

53 First engagement portion

53RS Recess

54 Second engagement portion

55 First opening

56 Second opening

61 Connection portion

62 Connection portion

63 Extension portion

71 Connection portion

72 Connection portion

73 Extension portion

75 First bus bar (first routing member)

75a First end portion

75b Second end portion

75c First extension portion

76 Second bus bar (second routing member)

76a Third end portion

76b Fourth end portion

76c Second extension portion

91 Insulating sheet

92 Heat transfer member

98 Cooler

θ1 First angle

θ2 Second angle

What is claimed is:

1. An electrical connection unit provided on a vehicle, comprising:
a base portion;
a first routing member that has a first extension portion extending in a direction intersecting the base portion and forms an energization path in a first direction intersecting the base portion; and
a second routing member that has a thermal load larger than that of the first routing member, has a second extension portion extending in a direction intersecting the base portion, and forms an energization path in the first direction,
wherein
the first extension portion is inclined at a first angle with respect to the base portion, and
the second extension portion is inclined at a second angle smaller than the first angle with respect to the base portion.

2. The electrical connection unit according to claim 1, wherein
the base portion includes one or more routing members,
the first routing member has a first end portion connected to the base portion and a second end portion located on a side opposite to the first end portion and disposed away from the base portion in the first direction,
the second routing member has a third end portion connected to the base portion and a fourth end portion located on a side opposite to the third end portion and disposed away from the base portion in the first direction,
the second end portion and the fourth end portion are disposed away from the base portion in the first direction by the same distance,
the first extension portion is an extension portion that connects the first end portion and the second end portion, and
the second extension portion is an extension portion that connects the third end portion and the fourth end portion.

3. The electrical connection unit according to claim 1, wherein
the first extension portion extends perpendicularly to the base portion, and
the second extension portion extends obliquely with respect to the base portion.

4. The electrical connection unit according to claim 1, further comprising a rigid member that includes a first plate portion facing the base portion in the first direction,
wherein
the first plate portion includes a first opening that overlaps at least a part of the first routing member when viewed in the first direction and a second opening that overlaps at least a part of the second routing member when viewed in the first direction, and
an opening area of the second opening is larger than an opening area of the first opening.

5. The electrical connection unit according to claim 4, wherein
the first extension portion extends to a side opposite to the base portion with respect to the first plate portion through the first opening, and
the second extension portion extends to a side opposite to the base portion with respect to the first plate portion through the second opening.

6. The electrical connection unit according to claim 1, further comprising:
a first electronic component; and
a second electronic component,
wherein
the base portion has a third routing member that connects the first routing member and the first electronic component and a fourth routing member that connects the second routing member and the second electronic component,
the fourth routing member is shorter than the third routing member, and
a distance between the second routing member and the second electronic component is shorter than a distance between the first routing member and the first electronic component.

7. The electrical connection unit according to claim 1, wherein
the second routing member extends obliquely with respect to the base portion, and
the base portion includes a fifth routing member disposed below a part of the second routing member.

8. The electrical connection unit according to claim 1, further comprising:
a sixth routing member; and
an insulating cover that accommodates the sixth routing member,
wherein
the second routing member extends obliquely with respect to the base portion, and
at least a part of the sixth routing member and at least a part of the insulating cover are disposed above a part of the second routing member.
